(19) United States
(12) Patent Application Publication
(10) Pub. No.: US 2025/0311212 A1
(43) Pub. Date: Oct. 2, 2025

(54) SEMICONDUCTOR DEVICE AND MANUFACTURING METHOD THEREOF

(71) Applicant: HON HAI PRECISION INDUSTRY CO., LTD., New Taipei City (TW)

(72) Inventors: Tien-Fan OU, Hsinchu City (TW); Yun-Hung SHEN, Hsinchu City (TW)

(21) Appl. No.: 18/679,425

(22) Filed: May 30, 2024

(30) Foreign Application Priority Data
Mar. 27, 2024 (TW) 113111555

(51) Int. Cl. H10B 41/70

(52) U.S. Cl. CPC H10B 41/70

(57) ABSTRACT

A semiconductor device includes a substrate, an oxide layer, two metal gates, two floating gates, and a common gate. The substrate includes plural active regions including first, second, central, third, and fourth active regions sequentially. The oxide layer is disposed on the substrate. Two metal gates are disposed on the oxide layer and respectively located between the first and second active regions and between the third and fourth active regions. Two floating gates are disposed on the oxide layer and respectively located between the second and central active regions and between the central and third active regions. Top surfaces of each of the metal gates and each of the floating gates are coplanar. The common gate is located above the central active region and part of each of the floating gates, and is isolated from the floating gates. A method of manufacturing a semiconductor device is also provided.

### CROSS-REFERENCE TO RELATED APPLICATION

This application claims priority to Taiwan Application Serial Number 113111555, filed Mar. 27, 2024, which is herein incorporated by reference.

### BACKGROUND

### Field of Invention

The present disclosure relates to a semiconductor device and a manufacturing method thereof. More particularly, the present disclosure relates to a semiconductor device embedded with a memory and a manufacturing method thereof.

### Description of Related Art

The current electronic devices have memories, and the memories can be divided into volatile or non-volatile memories. A volatile memory will lose data in the memory when there is no power. On the contrary, a non-volatile memory can still retain data when there is no power. With the evolution of technology, the shrinkage of transistor size contributes to allow the number of memories on a chip to increase.

However, the shrinkage of memory size also increases the difficulty of the process. As a result, there is a need to improve the current technology.

### SUMMARY

A semiconductor device is provided. The semiconductor device includes a substrate, an oxide layer, two metal gates, two floating gates, and a common gate. The substrate includes a body and a plurality of active regions disposed in a top of the body. The active regions include a first active region, a second active region, a central active region, a third active region, and a fourth active region in sequence. The oxide layer is disposed on the substrate and between the active regions. The two metal gates are disposed on the oxide layer and respectively located between the first active region and the second active region and between the third active region and the fourth active region. The two floating gates are disposed on the oxide layer and respectively located between the second active region and the central active region and between the central active region and the third active region. A top surface of each of the metal gates and a top surface of each of the floating gates are coplanar. The common gate is located above the central active region and located above part of each of the floating gates, and the common gate is isolated from the floating gates.

The present disclosure provides a semiconductor device. The semiconductor device includes a substrate, an oxide layer, two metal gates, two floating gates, and a common gate. The substrate includes a body and a plurality of active regions disposed in a top of the body. The active regions include a first active region, a second active region, a central active region, a third active region, and a fourth active region in sequence. The oxide layer is disposed on the substrate and between the active regions. The two metal gates are disposed on the oxide layer and respectively located between the first active region and the second active region and between the third active region and the fourth active region. The two floating gates are disposed on the oxide layer and respectively located between the second active region and the central active region and between the central active region and the third active region. The common gate includes a body and two extension portions. The body is located above the central active region. The two extension portions are respectively extended from a top of the body towards directions of the floating gates, and are respectively located above part of the floating gates.

The present disclosure further provides a method of manufacturing a semiconductor device. The method includes: providing a substrate, the substrate including a body and a plurality of active regions disposed in a top of the body, in which the active regions include a first active region, a second active region, a third active region, and a fourth active region in sequence; forming an oxide layer on the substrate and between the active regions; forming a floating gate layer on the oxide layer, and patterning the floating gate layer to obtain two dummy floating gates respectively between the first active region and the second active region and between the third active region and the fourth active region, and obtain two floating gates between the second active region and the third active region; forming a first interlayer dielectric layer on the substrate and the floating gate layer, and a top surface of the first interlayer dielectric layer and a top surface of the floating gate layer being coplanar; removing the dummy floating gates and respectively forming two metal gates, in which a top surface of each of the metal gates and the a top surface of each of the floating gates are coplanar; forming a second interlayer dielectric layer on the top surface of the first interlayer dielectric layer, the top surface of each of the metal gates, and the top surface of each of the floating gates; forming a central active region in the top of the body of the substrate and between the second active region and the third active region; and forming a common gate above the central active region and located above part of each of the floating gates, and the common gate being isolated from the floating gates.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows:

FIG. 1 to FIG. 7 respectively depict cross-sectional views of manufacturing a semiconductor device at different manufacturing stages according to one embodiment of the present disclosure.

### DESCRIPTION OF THE EMBODIMENTS

To make the contents of the present disclosure more thorough and complete, the following illustrative description is given with regard to the implementation aspects and embodiments of the present disclosure, which is not intended to limit the scope of the present disclosure. The various embodiments disclosed below can be combined or replaced with each other when beneficial, and other embodiment(s) may be added to one embodiment, without further description or illustration. In the following detailed description, for purposes of explanation, numerous specific details are set forth in order to provide a thorough understanding of the disclosed embodiments. It will be apparent, however, that one or more embodiments may be practiced without these specific details.

Currently, the high-k metal gate (HKMG) in a 28 nm process requires a gate height to be less than 500 angstroms (Å), otherwise, it is difficult to achieve the characteristics of 28 nm process. However, the gate height of the third-generation embedded flash memory (Embedded SuperFlash® 3, ESF3) is greater than 1000 Å, which is difficult to be compatible with the high-k metal gate in the 28 nm process. In addition, the process of the third-generation embedded flash memory is complex, and it requires a high voltage, such as a voltage higher than 10 volts, before it can be driven.

In view of the above, some embodiments of the present disclosure provide a semiconductor device embedded with a memory and a manufacturing method thereof. The gate height is less than 600 A, which is compatible with the high-k metal gate in the 28nm process, the process is simplified to have less than 13 mask steps, and the semiconductor device can be driven by a voltage lower than 5 volts without the need of high voltage.

Reference will now be made in detail to embodiments and experiment examples of the present disclosure, examples of which are described herein and illustrated in the accompanying drawings. While the semiconductor device and the manufacturing method thereof of the disclosure will be described in conjunction with embodiments and experiment examples, it will be understood that they are not intended to limit the disclosure to these embodiments and experiment examples. Therefore, the scope of the present disclosure is to be limited only by the appended claims.

In addition, while the method according to the present disclosure is illustrated and described below as a series of operations or steps, it will be appreciated that the illustrated ordering of such operations or steps are not to be interpreted in a limiting sense. For example, some operations or steps may occur in different orders and/or concurrently with other steps apart from those illustrated and/or described herein. Additionally, not all illustrated operations, steps and/or features may be required to implement one or more aspects or embodiments described herein. Also, each of the operations or steps disclosed herein may include several sub-steps or actions.

For the sake of clarity, features and elements that are well known in the art and are not necessary for understanding of the principles described have been omitted.

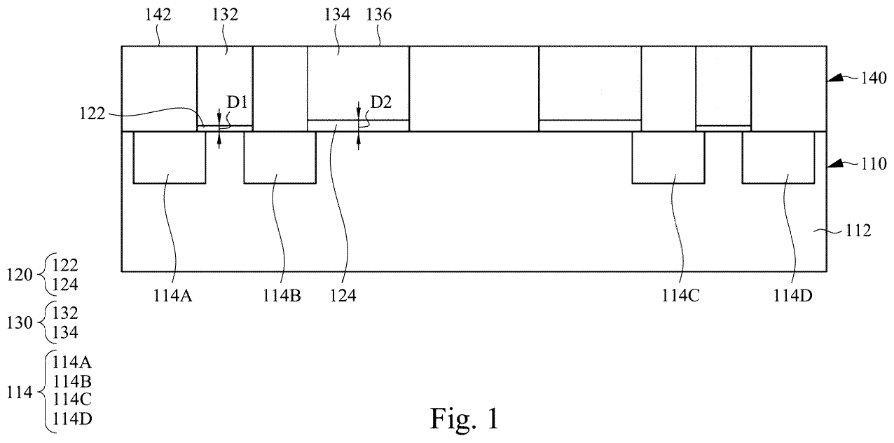

FIG. 1 to FIG. 7 respectively depict cross-sectional views of manufacturing a semiconductor device 100 at different manufacturing stages according to one embodiment of the present disclosure. A method of manufacturing the semiconductor device 100 includes step S11 to step S18.

In step S11, a substrate 110 is provided, as shown in FIG. 1. The substrate 110 is a silicon substrate. In some embodiments, the substrate 110 is a semiconductor-on-insulator substrate, such as a silicon-on-insulator (SOI) substrate, a silicon germanium-on-insulator (SGOI) substrate, or a germanium-on-insulator (GOI) substrate, which can be made of any suitable material(s). The substrate 110 includes a body 112 and a plurality of active regions 114 disposed in a top of the body 112. The active regions 114 include a first active region 114A, a second active region 114B, a third active region 114C, and a fourth active region 114D in sequence. In some embodiments, the first active region 114A on a leftmost side and the fourth active region 114D on a rightmost side are drains. The second active region 114B and the third active region 114C are not electrically connected to an external, that is, there is no wire electrically connected to the second active region 114B and there is no wire electrically connected to the third active region 114C. In some embodiments, the body 112 of the substrate 110 is P-type doped, and the active regions 114 are N-type doped. Or, the body 112 is N-type doped, and the active regions 114 are P-type doped.

In step S12, an oxide layer 120 is formed on the substrate 110, as shown in FIG. 1. In greater detail, depositing the oxide layer 120 on the substrate 110 is performed by, for example, chemical vapor deposition, physical vapor deposition, sputtering, or some other suitable deposition processes. The oxide layer 120 may include, for example, silicon oxide or some other suitable dielectrics. Then, the oxide layer 120 is patterned to form a thin oxide layer 122 (core oxide) and a thick oxide layer 124 (IO oxide, input/output oxide). The thin oxide layer 122 is located between the first active region 114A and the second active region 114B and between the third active region 114C and the fourth active region 114D. The thick oxide layer 124 is located between the second active region 114B and the third active region 114C. In some embodiments, the thin oxide layer 122 has a thickness D1 of about 20 Å or less than 20 Å, and the thick oxide layer 124 has a thickness D2 of about 50 Å or less than 50 Å, and the thickness D1 is less than the thickness D2. In some embodiments, a material of the oxide layer 120 is silicon oxide or some other suitable dielectrics.

In step S13, a floating gate layer 130 is formed on the oxide layer 120, as shown in FIG. 1. Depositing the floating gate layer 130 on the oxide layer 120 is performed by, for example, chemical vapor deposition, physical vapor deposition, sputtering, or some other suitable deposition processes. Then, the floating gate layer 130 is patterned to obtain two dummy floating gates 132 respectively between the first active region 114A and the second active region 114B and between the third active region 114C and the fourth active region 114D, and obtain two floating gates 134 between the second active region 114B and the third active region 114C. In greater detail, the dummy floating gates 132 are disposed on the thin oxide layer 122, and the floating gates 134 are disposed on the thick oxide layer 124. In some embodiments, the floating gate layer 130 may include, for example, doped polysilicon, metal, or some other suitable conductive materials.

In step S14, a first interlayer dielectric layer 140 is formed on the substrate 110 and the floating gate layer 130, as shown in FIG. 1. Then, the first interlayer dielectric layer 140 is planarized by performing, for example, chemical mechanical polish (CMP) or some other suitable planarization processes, so that a top surface 142 of the first interlayer dielectric layer 140 and a top surface 136 of the floating gate layer 130 are coplanar. The first interlayer dielectric layer 140 may include, for example, silicon nitride, silicon oxide, some other suitable dielectrics, or any combination thereof.

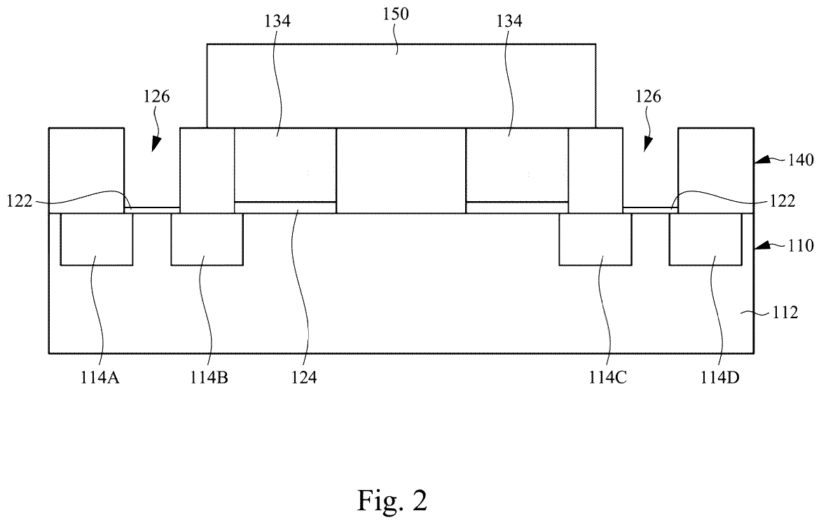

After that, as shown in FIG. 2, a first mask layer 150 is formed on part of the first interlayer dielectric layer 140 and the two floating gates 134. In greater detail, regions covered by the first mask layer 150 include: (1). part of the first interlayer dielectric layer 140 located between the left dummy floating gate 132 and the left floating gate 134 is covered, and the remaining part of the first interlayer dielectric layer 140 is exposed and not covered; (2). the top surfaces 136 of the two floating gates are covered; (3). the first interlayer dielectric layer 140 located between the floating gate 134 is covered; and (4). part of the first interlayer dielectric layer 140 located between the right dummy floating gate 132 and the right floating gate 134 is covered, and the remaining part of the first interlayer dielectric layer 140 is exposed and not covered. In some other embodiments, the first mask layer 150 covers the two floating gates 134 but exposes the two dummy floating gates 132 to facilitate removing the two dummy floating gates 132 subsequently. In some embodiments, the first mask layer 150 includes silicon oxide, silicon nitride, some other suitable dielectrics, or any combination thereof. The first mask layer 150 may be formed by, for example, chemical vapor deposition, physical vapor deposition, some other suitable deposition processes, or any combination thereof.

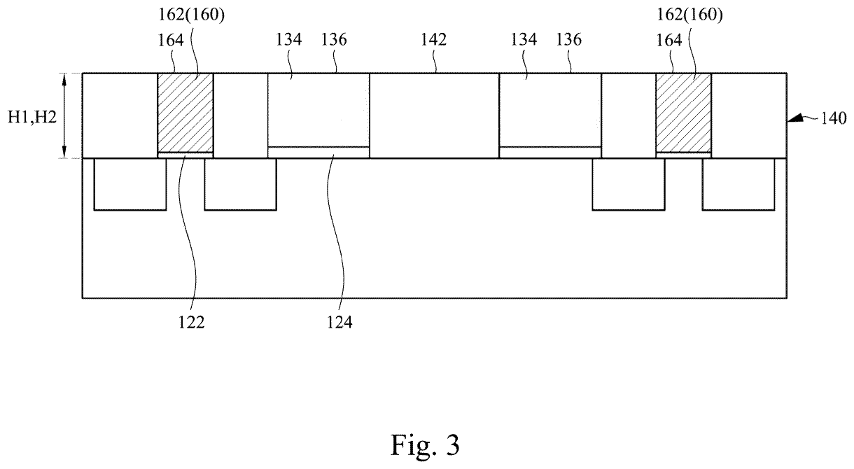

In step S15, these dummy floating gates 132 are removed and two metal gates 162 are respectively formed, as shown in FIG. 2 and FIG. 3. First, as shown in FIG. 2, these dummy floating gates 132 are removed. In greater detail, these dummy floating gates 132 are etched until the thin oxide layer 122 is exposed to form two openings 126. Next, as shown in FIG. 3, the first mask layer 150 is removed to expose the two floating gates 134 and the first interlayer dielectric layer 140. A metal gate layer 160 is thereafter filled in the two openings 126 to respectively form the two metal gates 162 disposed on the thin oxide layer 122. In some embodiments, the metal gate layer 160 is filled in the two openings 126, and then chemical mechanical polishing or some other suitable planarization process is performed, so that a top surface 164 of the metal gate layer 160, the top surface 136 of the floating gate layer 130, and the top surface 142 of the first interlayer dielectric layer 140 are coplanar. In some embodiments, a height H1 of each of the metal gates 162 plus the thin oxide layer 122 is the same as a height H2 of each of the floating gates 134 plus the thick oxide layer 124. For example, the height H1 and the height H2 are less than 600 Å. In some embodiments, the metal gate layer 160 may include, for example, metal or some other suitable conductive materials.

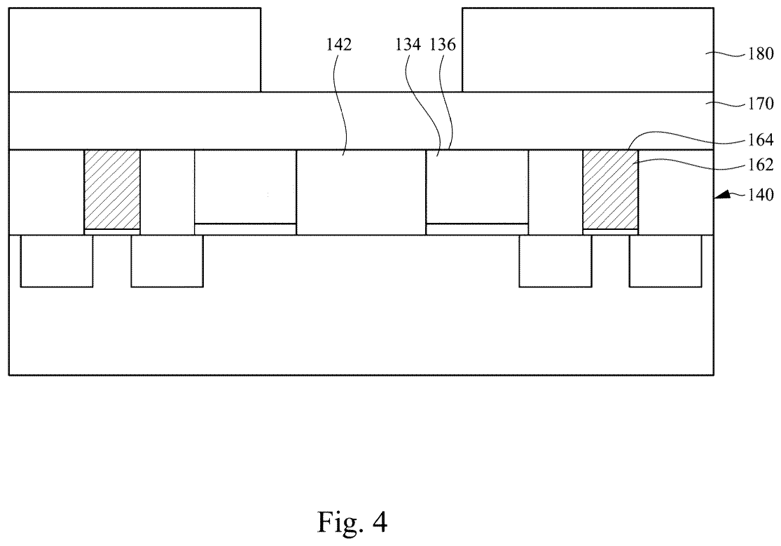

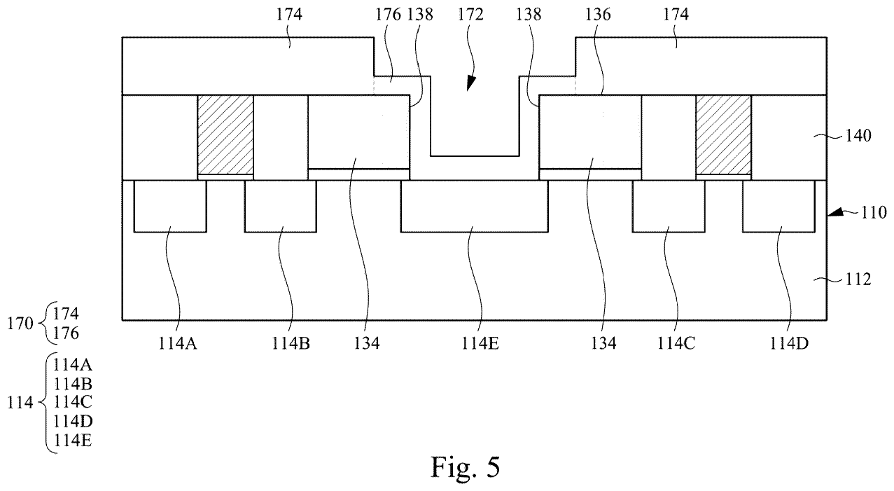

In step S16, a second interlayer dielectric layer 170 is formed on the top surface 142 of the first interlayer dielectric layer 140, the top surface 164 of each of the metal gates 162, and the top surface 136 of each of the floating gates 134, as shown in FIG. 4. Then, a second mask layer 180 is formed to cover a top of each of the metal gates 162 and a top of part of each of the floating gates 134. After that, as shown in FIG. 5, part of the first interlayer dielectric layer 140 and part of the second interlayer dielectric layer 170 are removed to form a T-shaped opening 172. In greater detail, the first interlayer dielectric layer 140 between the two floating gate 134 is removed, and part of the second interlayer dielectric layer 170 not covered by the second mask layer 180 is removed to form the T-shaped opening 172 and remaining second interlayer dielectric layer 174. Next, the second mask layer 180 is removed.

In step S17, a central active region 114E is formed in the top of the body 112 of the substrate 110, as shown in FIG. 5. The doped central active region 114E is located in the top of the body 112 of the substrate 110. The central active region 114E and the first active region 114A, the second active region 114B, the third active region 114C, and the fourth active region 114D have the same P-type or N-type dopants. Then, a conformal oxide layer 176 is formed on the central active region 114E, a side wall 138 and part of the top surface 136 of each of the floating gates 134. In some embodiments, a material of the conformal oxide layer 176 is the same as a material of the remaining second interlayer dielectric layer 174. In some embodiments, a region of a vertical projection of each of the floating gates 134 onto a bottom surface of the body 112 of the substrate 110 partially overlaps a region of a vertical projection of the central active region 114E onto the bottom surface of the body 112 of the substrate 110, so that the floating gates 134 and the central active region 114E can be conducted.

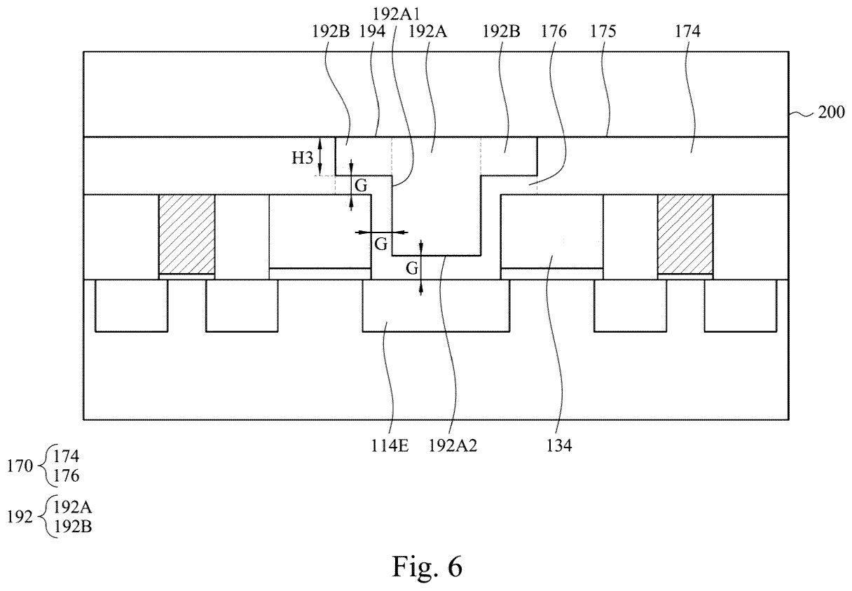

In step S18, a common gate 192 is formed above the central active region 114E and above part of each of the floating gates 134, and the common gate 192 is isolated from these floating gates 134 (not shown in the figure). In greater detail, a common gate layer is deposited on the conformal oxide layer 176 (that is, fills up the opening 172) and the remaining second interlayer dielectric layer 174. Then, the common gate layer is planarized by performing, for example, chemical mechanical polish (CMP) or some other suitable planarization processes, so that a top surface 194 of the common gate 192 and a top surface 175 of the remaining second interlayer dielectric layer 174 are coplanar. After that, as shown in FIG. 6, a third interlayer dielectric layer 200 is deposited on the top surface 194 of the common gate 192 and the top surface 175 of the remaining second interlayer dielectric layer 174. In some embodiments, the common gate 192 includes a body 192A and two extension portions 192B. The body 192A is located above the central active region 114E. The two extension portions 192B are respectively extended from a top of the body 192A towards directions of the floating gates 134, and are respectively isolated from the floating gates 134. Each of the extension portions 192B has a height H3, which is from 100 Å to 400 Å. A length extended by the extension portion 192B covers at least half an area of the top surface 136 of the floating gate 134. When the common gate 192 is used to erase memory, the extension portions 192B and a side portion 192A1 of the body 192A generate coupling voltages to the floating gates 134, and a lower portion 192A2 of the body 192A generates a coupling voltage to the central active region 114E and then to a source. In some embodiments, a distance G (a thickness of the conformal oxide layer 176) between the common gate 192 and each of the floating gates 134 is from 80 Å to 100 Å. If the distance G is excessively large, the retention of electrons in reliability is not good, and electrons easily leak and escape. On the contrary, if the distance G is excessively small, the coupling rate decreases. In some embodiments, the common gate 192 is in a T shape in cross section. In some embodiments, the common gate layer may include, for example, silicon nitride, silicon oxide, some other suitable dielectrics, or any combination thereof.

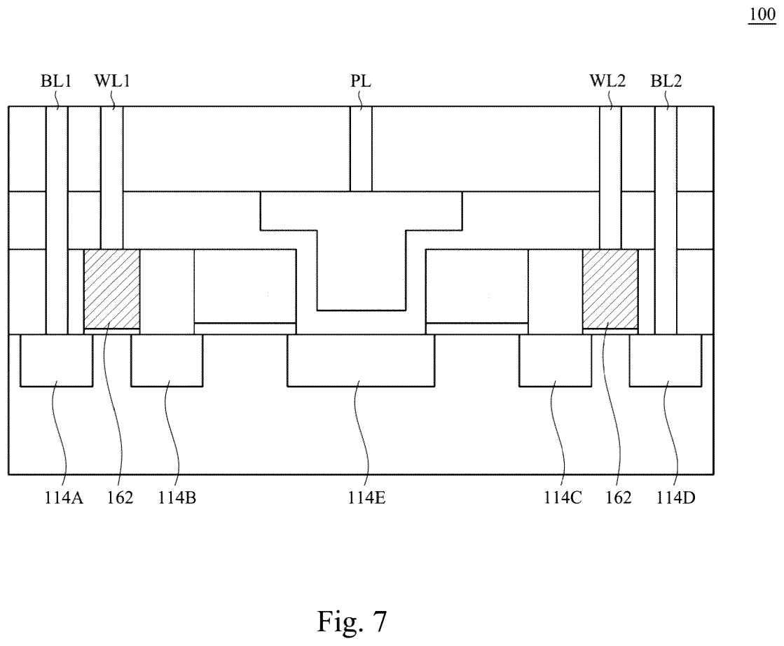

Next, as shown in FIG. 7, the first active region 114A and the fourth active region 114D are respectively electrically connected to a bit line BL1 and a bit line BL2. The central active region 114E is electrically connected to a source line (not shown in the figure), and each of the second active region 114B and the third active region 114C is electrically isolated. These metal gates 162 are respectively electrically connected to a word line WL1 and a word line WL2. The common gate 192 is electrically connected to a page line PL.

What is claimed is:

1. A semiconductor device comprising:
a substrate comprising a body and a plurality of active regions disposed in a top of the body, wherein the active regions comprise a first active region, a second active region, a central active region, a third active region, and a fourth active region in sequence;
an oxide layer disposed on the substrate and between the active regions;
two metal gates disposed on the oxide layer and respectively located between the first active region and the second active region and between the third active region and the fourth active region;
two floating gates disposed on the oxide layer and respectively located between the second active region and the central active region and between the central active region and the third active region, wherein a top surface of each of the metal gates and a top surface of each of the floating gates are coplanar; and
a common gate located above the central active region and located above part of each of the floating gates, and the common gate being isolated from the floating gates.

2. The semiconductor device of claim 1, wherein the oxide layer comprises a thin oxide layer disposed on the substrate and between the first active region and the second active region and between the third active region and the fourth active region.

3. The semiconductor device of claim 2, wherein the oxide layer further comprises a thick oxide layer disposed on the substrate and between the second active region and the central active region and between the central active region and the third active region.

4. The semiconductor device of claim 2, wherein the metal gates are disposed on the thin oxide layer.

5. The semiconductor device of claim 3, wherein the floating gates are disposed on the thick oxide layer.

6. The semiconductor device of claim 1, wherein the common gate comprises:
a body located above the central active region; and
two extension portions being respectively extended from a top of the body towards directions of the floating gates, and being respectively isolated from the floating gates.

7. The semiconductor device of claim 1, wherein a height of each of the metal gates is less than 600 angstroms (Å).

8. The semiconductor device of claim 1, wherein a distance between the common gate and each of the floating gates is from 80 Å to 100 Å.

9. The semiconductor device of claim 1, wherein a region of a vertical projection of each of the floating gates onto a bottom surface of the body of the substrate partially overlaps a region of a vertical projection of the central active region onto the bottom surface of the body of the substrate.

10. A semiconductor device comprising:
a substrate comprising a body and a plurality of active regions disposed in a top of the body, wherein the active regions comprise a first active region, a second active region, a central active region, a third active region, and a fourth active region in sequence;
an oxide layer disposed on the substrate and between the active regions;
two metal gates disposed on the oxide layer and respectively located between the first active region and the second active region and between the third active region and the fourth active region;
two floating gates disposed on the oxide layer and respectively located between the second active region and the central active region and between the central active region and the third active region; and
a common gate comprising:
a body located above the central active region; and
two extension portions being respectively extended from a top of the body towards directions of the floating gates, and respectively located above part of the floating gates.

11. The semiconductor device of claim 10, wherein a top surface of each of the metal gates and a top surface of each of the floating gates are coplanar.

12. The semiconductor device of claim 10, wherein the common gate being is isolated from each of the floating gates.

13. The semiconductor device of claim 12, wherein a distance between the common gate and each of the floating gates is from 80 Å to 100 Å.

14. A method of manufacturing a semiconductor device comprising:
providing a substrate, the substrate comprising a body and a plurality of active regions disposed in a top of the body, wherein the active regions comprise a first active region, a second active region, a third active region, and a fourth active region in sequence;
forming an oxide layer on the substrate and between the active regions;
forming a floating gate layer on the oxide layer, and patterning the floating gate layer to obtain two dummy floating gates respectively between the first active region and the second active region and between the third active region and the fourth active region, and obtain two floating gates between the second active region and the third active region;
forming a first interlayer dielectric layer on the substrate and the floating gate layer, and a top surface of the first interlayer dielectric layer and a top surface of the floating gate layer being coplanar;
removing the dummy floating gates and respectively forming two metal gates, wherein a top surface of each of the metal gates and the a top surface of each of the floating gates are coplanar;
forming a second interlayer dielectric layer on the top surface of the first interlayer dielectric layer, the top surface of each of the metal gates, and the top surface of each of the floating gates;
forming a central active region in the top of the body of the substrate and between the second active region and the third active region; and
forming a common gate above the central active region and located above part of each of the floating gates, and the common gate being isolated from the floating gates.

15. The method of claim 14, wherein the step of forming the oxide layer comprises:
forming the oxide layer on the substrate; and
patterning the oxide layer to form a thin oxide layer and a thick oxide layer, wherein the thin oxide layer is between the first active region and the second active region and between the third active region and the fourth active region, the thick oxide layer is between the second active region and the third active region.
